(19) United States
(12) Patent Application Publication
(10) Pub. No.: US 2023/0220556 A1
(43) Pub. Date: Jul. 13, 2023

(54) PLATED METALLIC SUBSTRATES AND METHODS OF MANUFACTURE THEREOF

(71) Applicant: Westinghouse Electric Company LLC, Cranberry Township, PA (US)

(72) Inventors: Benjamin R. MAIER, Pittsburgh, PA (US); Allan W. JAWORSKI, Canonsburg, PA (US); Jorie L. WALTERS, Columbia, SC (US)

(73) Assignee: Westinghouse Electric Company LLC, Cranberry Township, PA (US)

(21) Appl. No.: 17/997,745

(22) PCT Filed: Apr. 27, 2021
(86) PCT No.: PCT/US2021/029344

§ 371 Date: Nov. 2, 2022

Related U.S. Application Data
(60) Provisional application No. 63/016,174, filed on Apr. 27, 2020.

(51) Int. Cl. C23C 28/02; B32B 15/01; C25D 7/04; C25D 3/06; C23C 14/02; C23C 14/16; C22C 16/00; G21C 3/07; G21C 21/14

(52) U.S. Cl. CPC C23C 28/021; B32B 15/01; C23C 28/023; C25D 7/04; C25D 3/06; C23C 14/022; C23C 14/025; C23C 14/16; C22C 16/00; G21C 3/07; G21C 21/14

(57) ABSTRACT

Plated metallic substrates and methods of manufacture are provided. The method comprises depositing a first layer onto at least a portion of the metallic substrate to create a coated substrate utilizing physical vapor deposition. The method comprises electroplating a second layer comprising chromium, a chromium alloy, or a combination thereof onto at least a portion of the first layer to create a plated substrate.

### CROSS-REFERENCE TO RELATED APPLICATION

This application claims the benefit of U.S. Provisional Application Ser. No. 63/016,174 filed Apr. 27, 2020, the contents of which is hereby incorporated by reference in its entirety herein.

### GOVERNMENT SUPPORT

This invention was made with government support under Government Contract No. DE-NE0008824 awarded by the Department of Energy. The government has certain rights in the invention.

### BACKGROUND

Light water reactors (LWRs), such as, for example, pressurized water reactors (PWRs) can comprise nuclear fuel rods suitable for holding nuclear fuel. The nuclear fuel can comprise uranium, a uranium alloy, plutonium, a plutonium alloy, thorium, a thorium alloy, or a combination thereof. Some nuclear fuel rods comprise zirconium or a zirconium alloy, such as, for example, ZIRLO® provided by Westinghouse Electric Company, Cranberry Township, Pennsylvania. The nuclear fuel rods can be subjected to various corrosive processes during operation in a PWR, such as, for example, waterside corrosion and hydrogen pickup. There are challenges with the manufacturability and enhancing corrosion performance of nuclear fuel rods comprising zirconium or a zirconium alloy,

### SUMMARY

The present disclosure provides a method for processing a metallic substrate. The method comprises depositing a first layer onto at least a portion of the metallic substrate to create a coated substrate utilizing physical vapor deposition, the first layer is configured to be electroplated. The method comprises electroplating a second layer comprising chromium, a chromium alloy, or a combination thereof onto at least a portion of the first layer to create a plated substrate.

The present disclosure also provides a plated nuclear fuel rod comprising a substrate, a first layer, and a second layer. The substrate comprises zirconium or a zirconium alloy. The first layer is deposited by physical vapor deposition over the substrate. A thickness of the first layer is in a range of 0.1 microns to 5 microns. The second layer is deposited by electroplating. The second layer comprises chromium, a chromium alloy, or a combination thereof. A thickness of the second layer is in a range of 0.1 microns to 50 microns.

It is understood that the inventions described in this specification are not limited to the examples summarized in this Summary. Various other aspects are described and exemplified herein.

### BRIEF DESCRIPTION OF THE DRAWINGS

The features and advantages of the examples, and the manner of attaining them, will become more apparent, and the examples will be better understood by reference to the following description of examples taken in conjunction with the accompanying drawing, wherein:

FIG. 1 is a schematic process diagram illustrating an example of a method for processing a zirconium or zirconium alloy nuclear fuel rod according to the present disclosure.

FIG. 2 is a schematic diagram illustrating an example of a portion of a plated nuclear fuel rod according to the present disclosure.

Corresponding reference characters indicate corresponding parts throughout the several views. The exemplifications set out herein illustrate certain examples, in one form, and such exemplifications are not to be construed as limiting the scope of the examples in any manner.

### DETAILED DESCRIPTION

Certain exemplary aspects of the present disclosure will now be described to provide an overall understanding of the principles of the composition, function, manufacture, and use of the compositions, articles, and methods disclosed herein, An example or examples of these aspects are illustrated in the accompanying drawing, Those of ordinary skill in the art will understand that the compositions, articles, and methods specifically described herein and illustrated in the accompanying drawing are non-limiting exemplary aspects and that the scope of the various examples of the present invention is defined solely by the claims. The features illustrated or described in connection with one exemplary aspect may be combined with the features of other aspects. Such modifications and variations are intended to be included within the scope of the present invention.

Reference throughout the specification to “various examples,” “some examples,” “one example,” “an example,” or the like, means that a particular feature, structure, or characteristic described in connection with the example is included in an example. Thus, appearances of the phrases “in various examples,” “in some examples,” “in one example,” “in an example,” or the like, in places throughout the specification are not necessarily all referring to the same example. Furthermore, the particular features, structures, or characteristics may be combined in any suitable manner in an example or examples. Thus, the particular features, structures, or characteristics illustrated or described in connection with one example may be combined, in whole or in part, with the features, structures, or characteristics of another example or other examples without limitation. Such modifications and variations are intended to be included within the scope of the present examples.

As used in this specification, particularly in connection with coating layers or the terms “on” “onto,” “over,” and variants thereof (e.g., “applied over,” “formed over,” “deposited over,” “provided over,” “located over,” “electroplated over,” and the like) mean applied, formed, deposited, provided, or otherwise located over a surface of a substrate but not necessarily in contact with the surface of the substrate. For example, a coating layer “applied over” a substrate does not preclude the presence of another coating layer or other coating layers of the same or different composition located between the applied coating layer and the substrate. Likewise, a second coating layer “applied over” a first coating layer does not preclude the presence of another coating layer or other coating layers of the same or different composition located between the applied second coating layer and the applied first coating layer.

As used herein, “intermediate” means that the referenced element is disposed between two elements but is not necessarily in contact with those elements. Accordingly, unless stated otherwise herein, an element that is “intermediate” a first element and a second element may or may not be adjacent to or in contact with the first and/or second elements, and other elements may be disposed between the intermediate element and the first and/or second elements.

LVVRs, such as, for example, PVVRs comprise nuclear fuel rods for supporting nuclear fuel within the reactor. Typically, the nuclear fuel rods comprise a tubular shape and in various examples comprise a length of 4 meters, an external diameter of 1 centimeter (cm), and a wall thickness of 0.6 millimeters (mm). The nuclear fuel rods can comprise zirconium or zirconium alloy. The nuclear fuel rods can be a barrier against the release of fission products from the nuclear fuel into the primary circuit of a PWR. Therefore, it may be desirable to enhance the corrosion performance of nuclear fuel rods to in order to maintain a desirable barrier against the release of fission products from the nuclear fuel and enhance the high temperature performance of the nuclear fuel rods.

The inventors of the present disclosure have found that cold spraying thin layers (e.g., no greater than 5 microns) of chromium or a chromium alloy can present challenges. Additionally, the inventors have found physical vapor deposition may have an undesirable deposition rate (e.g., 1 micron per hour) thereby impeding formation of a thick layer by physical vapor deposition. Furthermore, the inventors of the present disclosure have determined that a faster deposition rate (e.g., 12 to 15 microns per hour) can be achieved utilizing chrome or chrome alloy electroplating. However, the present inventors also determined that zirconium or zirconium alloy nuclear fuel rods may not be directly electroplated with chrome due to the presence of zirconium oxide, which is typically present on the surface of zirconium or zirconium alloy nuclear fuel rods. For example, the chemical bath used for electroplating chrome typically cannot remove enough, if any, zirconium oxide for the chromium or chromium alloy to be properly electroplated to the surface of the zirconium or zirconium alloy nuclear fuel rod.

Thus, the present disclosure provides a method for processing a zirconium or zirconium alloy nuclear fuel rod that can apply a desired layer thickness of chromium or a chromium alloy for corrosion prevention at a desired deposition rate. Additionally, the present disclosure provides a plated nuclear fuel rod that can be suitable for rapid manufacture while enhancing corrosion resistance. The plated nuclear fuel rods according to the present disclosure can be accident tolerant and suitable for LWRs, such as, for example, PVVRs.

Additionally, the present disclosure may also be applicable to other metallic substrates which may not be directly electroplated with chrome. For example, the present disclosure may be applicable to nuclear fuel rods, aerospace components, chemical processing components, or a combination thereof. The metallic substrate can comprise zirconium, a zirconium alloy, titanium, a titanium alloy, hafnium, a hafnium alloy or a combination thereof. For ease of clarify, the metallic substrate will be described in terms of a nuclear fuel rod comprising zirconium or a zirconium alloy but it would be understood, the nuclear fuel rod comprising zirconium or a zirconium alloy could include or be replaced by or additionally include other types of metallic substrates, such an aerospace component, a chemical processing component, or other component.

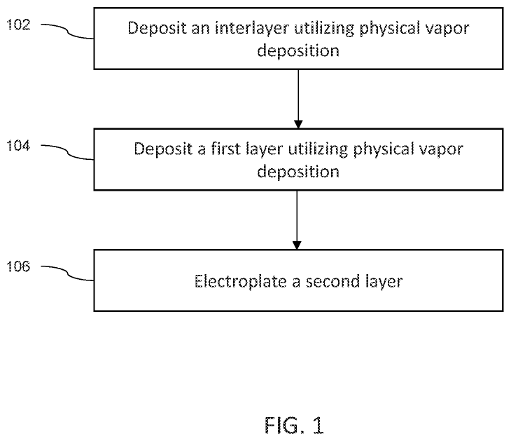

Referring to FIG. 1, a method of processing a zirconium or a zirconium alloy nuclear fuel rod is provided. As illustrated, an optional interlayer may be deposited onto the nuclear fuel rod prior to a first layer, 102. The interlayer can be deposited by physical vapor deposition which may include pre-deposition ion etching of the surface of the nuclear fuel rod. In various examples, depositing the interlayer removes at least a portion of zirconium oxide on a surface of the nuclear fuel rod.

Thereafter, a first layer can be deposited onto at least a portion of the nuclear fuel rod to create a coated nuclear fuel rod utilizing physical vapor deposition, 104. In examples where the first layer is applied directly to the nuclear fuel rod, it may be desirable for the physical vapor deposition of the first layer to include pre-deposition ion etching of the surface of the nuclear fuel rod or interlayer. In various examples, depositing the first layer removes at least a portion of zirconium oxide on a surface of the nuclear fuel rod. The first layer can be electrically conductive and suitable for electroplating. For example, the first layer can enable a subsequent electroplating process which may not have been able to occur without the first layer.

Physical vapor deposition can occur under at least a partial vacuum and can include sputtering or evaporation. For example, physical vapor deposition can comprise vaporization of a solid source material utilizing high temperatures or a plasma, transporting the vaporized solid source material to the surface of the nuclear fuel rod, and condensing the vaporized solid source material into the desired layer (e.g., interlayer, first layer) on the nuclear fuel rod. In various examples, solid source material can comprise the desired composition to be deposited onto the nuclear fuel rod. In examples where the first layer is being deposited, the solid source material can comprise chromium, a chromium alloy, iron, an iron alloy, tantalum, a tantalum alloy, tungsten, a tungsten alloy, molybdenum, a molybdenum alloy, niobium, a niobium alloy, or a combination thereof. In examples where the first layer is being deposited, the solid source material can comprise chromium, a chromium alloy, iron, an iron alloy, or a combination thereof. In examples where the interlayer is being deposited, the solid source material can comprise tantalum, a tantalum alloy, tungsten, a tungsten alloy, molybdenum, a molybdenum alloy, niobium, a niobium alloy, or a combination thereof. In various examples, physical vapor deposition can comprise magnetron sputtering or pulsed magnetron sputtering.

A second layer can be electroplated onto at least a portion of the first layer to create a plated nuclear fuel rod, 106. For example, the second layer can be directly in contact with the first layer. The first layer can be suitable for receiving an electroplated second layer since an oxide, if any, formed by physical vapor deposition of the first layer can be at least partially removed via an electroplating process in order to achieve a desired bonding between the first layer and the second layer. The second layer can be a corrosion resistant (e.g., oxidation resistant) andior wear resistant layer suitable for use in a PAR. The second layer can be electroplated at a faster rate than the first layer thereby enhancing manufacture of the plated nuclear fuel rod and enabling formation of thicker layers of chromium or a chromium alloy. For example, the second layer can be electroplated at a rate that is at least 10 times faster than a rate the first layer is deposited.

Electroplating can comprise an optional initial cleaning of the nuclear fuel rod to remove dirt or other surface impurities, an optional pretreatment of the nuclear fuel rod such as etching, submerging at least a portion of the nuclear fuel rod in a chemical bath, and forming an electrical potential between the nuclear fuel rod and the chemical bath. The chemical bath can comprise a chromium or chromium alloy based ingredient (e.g., chromium trioxide, chromium sulfate, chromium chloride) and an electrolyte (e.g., sulfuric acid). The temperature of the chemical bath can be controlled to achieved desired properties of the second layer formed by the electroplating.

The plated nuclear fuel rod can comprise the first layer, the second layer and optionally the interlayer and/or other layers. In various examples, the first layer is directly deposited onto the nuclear fuel rod and the second layer is directly electroplated to the first layer. In other examples, the interlayer is directly deposited onto the nuclear fuel rod, the first layer is directly deposited onto the interlayer, and the second layer is directly deposited onto the first layer. In some examples, another layer is deposited intermediate the nuclear fuel rod and the interlayer and/or intermediate the interlayer and the first layer.

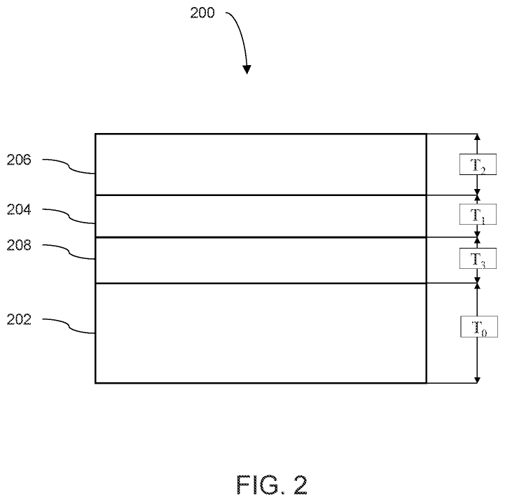

A portion of a plated nuclear fuel rod 200 according to the present disclosure is illustrated in FIG. 2. As illustrated, the plated nuclear fuel rod 200 comprises a substrate 202, a first layer 204, a second layer 208, and an optional interlayer 208.

The substrate 202 can comprise zirconium or a zirconium alloy. For example, the substrate can comprise pure zirconium, Zircaloy-2™, Zircaloy-4™, ZIRLO® , Optimized ZIRLO™, or a combination thereof. For example, the substrate 202 can comprise a zirconium alloy composition comprising, all based on the total weight of the zirconium alloy: 0.5% to 2.0% niobium; 0.7% to 1.5% tin; 0.07% to 0.14% iron; up to 0.03% carbon; up to 0.2% oxygen; and balance zirconium and incidental impurities.

The substrate 202 can be tubular in shape and can comprise a wall thickness, to, in a range of 0.4 mm to 0.7 mm, such as, for example, 0.5 mm to 0.6 mm. In various examples, the thickness, t₀, can be 0.57 mm. The external diameter of the substrate 202 can be in a range of 7 mm to 12 mm, such as, for example, 8 mm to 11 mm or 9 mm to 10 mm. In various examples, the external diameter of the substrate 202 can be 9.5 mm.

The first layer 204 can be deposited by physical vapor deposition over the substrate 202 and in examples comprising the interlayer 208, the first layer 204 can be deposited over the interlayer 208. The first layer 204 can provide a surface suitable for electroplating. For example, the first layer 204 can be suitably bonded to a layer directly underneath the first layer 204. In certain examples without the interlayer 208, the first layer 204 can be directly bonded to zirconium or zirconium alloy portions of the substrate 202 by the physical vapor deposition process such that zirconium oxide may be minimally, if at all present, between the first layer 204 and the substrate 202.

The first layer 204 can comprise a composition suitable for electroplating. For example, the first layer 204 can comprise chromium, chromium alloy, iron, an iron alloy, or a combination thereof. In various examples, the first layer 204 can comprise chromium or a chromium alloy.

The first layer 204 can comprise a thickness, t₁, of at least 0.1 microns, such as, for example, at least 1 micron, at least 2 microns, at least 3 microns, or at least 4 microns. In various examples, the thickness, t₁, can be no greater than 5 microns, such as, for example, no greater than 4 microns, no greater than 3 microns, or no greater than 2 microns. For example, the thickness, t₁, can be in a range of 0.1 microns to 5 microns, such as, for example, 1 micron to 5 microns, 1 micron to 4 microns, 2 microns to 4 microns, 3 microns to 5 microns, or 3 microns to 4 microns. The thickness of the first layer 204 can be selected to achieve a suitable surface for electroplating.

The second layer 206 can be deposited by electroplating over the first layer 204. For example, the second layer 206 can be in direct contact with the first layer 204. The second layer 206 can be suitable for operation in PWRs. For example, the second layer 206 can enhance the corrosion resistance of the plated nuclear fuel rod 200. The second layer comprising chromium, a chromium alloy, or a combination thereof. The utilization of physical vapor deposition for creating the first layer 204 and the subsequent use of electroplating for the second layer 206 enables the plated nuclear fuel rod 200 to have enhanced adhesion between layers, enhanced layer compositional properties, and increase thicknesses of the second layer 206. In various examples, the second layer 206 is the outermost layer of the plated nuclear fuel rod 200.

In examples, where the first layer 204 comprises chromium or a chromium alloy, utilizing physical vapor deposition for the first layer 204 can enhance mixing of the zirconium or zirconium alloy of the substrate 202 with the chrome or chromium alloy of the first layer 204 through ion bombardment if the physical vapor deposition target and the substrate 202 are oppositely biased. In certain examples, the microstructures of the first layer 204 and second layer 206 can be different due to different growth mechanisms. For example, the second layer 206 may be more dense than the first layer 204. However, in some examples, during deposition of the first layer 204, the film energy can be maintained at a high level by heating the substrate or using a higher energy process that bombards the surface with ions during the deposition. This may be challenging for a zirconium or a zirconium alloy substrate because they typically have a heat treated microstructure. In various examples, increasing the thickness of the first layer 204 may be challenging because of stresses that build up in the first layer 204 due to the physical vapor deposition process that may crack or delaminate the first layer 204. In various examples, the second layer 206 comprises an improved grain structure compared to the first layer 204 since the physical vapor deposition process may result in a columnar grain structure which may not be conducive to corrosion protection.

The second layer 206 can comprise a thickness, t₂, of at least 0.1 microns, such as, for example, at least 5 microns, at least 10 microns, at least 15 microns, at least 20 microns, at least 25 microns, or at least 30 microns. In various examples, the thickness, t₂, can be no greater than 50 microns, such as, for example, no greater than 40 microns, no greater than 30 microns, no greater than 25 microns, no greater than 20 microns, no greater than 15 microns, or no greater than 10 microns. For example, the thickness, t₂, can be in a range of 0.1 microns to 50 microns, such as, for example, 5 microns to 50 microns, 5 microns to 40 microns, 10 microns to 50 microns, or 15 microns to 50 microns,

The interlayer 208 can be deposited by physical vapor deposition over the substrate 202. For example, the interlayer 208 can be in direct contact with the substrate 202. The interlayer 208 can comprise tantalum, a tantalum alloy, tungsten, a tungsten alloy, molybdenum, a molybdenum alloy, niobium, a niobium alloy, or a combination thereof. In certain examples, the interlayer 208 can comprise tantalum, a tantalum alloy, tungsten, a tungsten alloy, niobium, a niobium alloy, or a combination thereof. For example, the interlayer 208 can comprise niobium or a niobium alloy. The interlayer 208 can minimize or prevent the formation of a eutectic alloy from the substrate 202 and the first layer 204. For example, the interlayer 208 can be configured to minimize or prevent the formation of an eutectic alloy comprising zirconium and chromium. The interlayer 208 can inhibit oxidation of the substrate 202 and enable higher operating temperatures of the plated nuclear fuel rod 200. For example, the plated nuclear fuel rod 200 can operate in a PWR at temperatures greater than 900 degrees Celsius.

The interlayer 208 can comprise a thickness, t₃, of at least 0.01 micron, such as, for example, at least 1 micron, at least 2 microns, at least 3 microns, at least 4 microns, or at least 5 microns. The thickness, t₃, can be no greater than 10 microns, such as, for example, no greater than 9 microns, no greater than 7 microns, no greater than 6 microns, no greater than 5 microns, no greater than 4 microns, or no greater than 3 microns. For example, the thickness, t₃, can be in a range of 0.01 microns to 10 microns, such as, for example, 1 micron to 10 microns, 3 microns to 7 microns, or 4 microns to 6 microns. The thickness, t₃, can be selected to achieve a desired resistance to eutectic alloy formation between the substrate 202 and the first layer 204.

The plated nuclear fuel rod 200 can comprise the substrate 202, the first layer 204, the second layer 206, and optionally the interlayer 208 and/or other layers. In various examples, the first layer 204 is directly deposited onto the substrate 202 and the second layer 206 is directly electroplated to the first layer 204, In other examples as shown in FIG. 2, the interlayer 208 is directly deposited onto the substrate 202, the first layer 204 is directly deposited onto the interlayer 208, and the second layer 206 is directly deposited onto the first layer 204. In some examples, another layer (not shown) is deposited intermediate the substrate 202 and the interlayer 208 and/or intermediate the interlayer 208 and the first layer 204.

Various aspects of the invention according to the present disclosure include, but are not limited to, the aspects listed in the following numbered clauses.
1. A method for processing a metallic substrate, the method comprising: depositing a first layer onto at least a portion of the metallic substrate to create a coated substrate utilizing physical vapor deposition, the first layer is configured to be electroplated: and electroplating a second layer comprising chromium, a chromium alloy, or a combination thereof onto at least a portion of the first layer to create a plated substrate,
2. The method of clause 1, wherein the physical vapor deposition comprises ion etching.
3. The method of any one of clauses 1-2, wherein the first layer comprises chromium, chromium alloy, iron, an iron alloy, tantalum, a tantalum alloy, tungsten, a tungsten alloy, molybdenum, a molybdenum alloy, niobium, a niobium alloy, or a combination thereof.
4. The method of any one of clauses 1-3, wherein the first layer comprises a thickness in a range of 0.1 microns to 5 microns.
5. The method of any one of clauses 1-4, further comprising depositing an interlayer onto the metallic substrate prior to the first layer, wherein the interlayer comprises tantalum, a tantalum alloy, tungsten, a tungsten alloy, molybdenum, a molybdenum alloy, niobium, a niobium alloy, or a combination thereof.
6. The method of clause 5, wherein the interlayer comprises a thickness in a range of 0.01 microns to 10 microns.
7. The method of any one of clauses 5-6, wherein the metallic substrate comprises a zirconium or zirconium alloy nuclear fuel rod and the depositing the interlayer removes at least a portion of zirconium oxide on a surface of the nuclear fuel rod.
8. The method of any one of clauses 1-4, wherein the metallic substrate comprises a zirconium or zirconium alloy nuclear fuel rod and the depositing the first layer removes at least a portion of zirconium oxide on a surface of the nuclear fuel rod.
9. The method of any one of clauses 1-8, wherein the second layer comprises a thickness in a range of 0.1 microns to 50 microns.
10. The method of any one of clauses 1-9, wherein the first layer comprises a thickness in a range of 3 microns to 5 microns and the second layer comprises a thickness of greater than 15 microns.
11. The method of any one of clauses 1-10, wherein the metallic substrate comprises a nuclear fuel rod and wherein the nuclear fuel rod comprises a zirconium alloy composition comprising, all based on the total weight of the zirconium alloy:
   0.5% to 2.0% niobium:
   0.7% to 1.5% tin;
   0.07% to 0.14% iron;
   up to 0.03% carbon;
   up to 0.2% oxygen; and
   balance zirconium and incidental impurities.
12. The method of any one of clauses 1-11, wherein the plated substrate is suitable for use in a pressurized water reactor.
13. The method of any one of clauses 1-12, wherein the second layer is electroplated at a rate that is at least 10 times faster than a rate the first layer is deposited.
14. A plated nuclear fuel rod comprising:
   a substrate comprising zirconium or a zirconium alloy;
   a first layer deposited by physical vapor deposition over the substrate, a thickness of the first layer in a range of 0.1 microns to 5 microns;
   a second layer deposited by electroplating, the second layer comprising chromium, a chromium alloy, or a combination thereof, a thickness of the second layer is in a range of 0.1 microns to 50 microns.
15. The plated nuclear fuel rod of clause 14, wherein the first layer comprises chromium, chromium alloy, iron, an iron alloy, or a combination thereof.
16. The plated nuclear fuel rod of any one of clauses 14-15, further comprising an interlayer intermediate the substrate and the first layer, wherein the interlayer comprises tantalum, a tantalum alloy, tungsten, a tungsten alloy, molybdenum, a molybdenum alloy, niobium, a niobium alloy, or a combination thereof.
17. The plated nuclear fuel rod of clause 16, wherein the interlayer comprises a thickness in a range of 0.01 microns to 10 microns.
18. The plated nuclear fuel rod of any one of clauses 14-17, wherein the first layer comprises a thickness in a range of 3 microns to 5 microns and the second layer comprises a thickness of greater than 15 microns.
19. The plated nuclear fuel rod of any one of clauses 14-18, wherein the substrate comprises a zirconium alloy composition comprising, all based on the total weight of the zirconium alloy:
   0.5% to 2.0% niobium;
   0.7% to 1.5% tin;
   0.07% to 0.14% iron;
   up to 0.3% carbon;
   up to 0.2% oxygen; and
   balance zirconium and incidental impurities.
20. The plated nuclear fuel rod of any one of clauses 14-19, wherein the nuclear fuel rod is suitable for use in a pressurized water reactor.

Those skilled in the art will recognize that the herein described compositions, articles, methods, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Various features and characteristics are described in this specification to provide an understanding of the composition, structure, production, function, and/or operation of the invention, which includes the disclosed compositions, coatings, and methods. It is understood that the various features and characteristics of the invention described in this specification can be combined in any suitable manner, regardless of whether such features and characteristics are expressly described in combination in this specification. The Inventors and the Applicant expressly intend such combinations of features and characteristics to be included within the scope of the invention described in this specification. As such, the claims can be amended to recite, in any combination, any features and characteristics expressly or inherently described in, or otherwise expressly or inherently supported by, this specification. Furthermore, the Applicant reserves the right to amend the claims to affirmatively disclaim features and characteristics that may be present in the prior art, even if those features and characteristics are not expressly described in this specification. Therefore, any such amendments will not add new matter to the specification or claims and will comply with the written description, sufficiency of description, and added matter requirements.

With respect to the appended claims, those skilled in the art will appreciate that recited operations therein may generally be performed in any order. Also, although various operational flows are presented in a sequence(s), it should be understood that the various operations may be performed in other orders than those that are illustrated or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

The invention(s) described in this specification can comprise, consist of, or consist essentially of the various features and characteristics described in this specification. The terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. Thus, a composition, nuclear fuel rod, or method that “comprises,” “has,” “includes,” or “contains” a feature or features and/or characteristics possesses the feature or those features and/or characteristics but is not limited to possessing only the feature or those features and/or characteristics. Likewise, an element of a composition, coating, or process that “comprises,” “has,” “includes,” or “contains” the feature or features and/or characteristics possesses the feature or those features and/or characteristics but is not limited to possessing only the feature or those features and/or characteristics and may possess additional features and/or characteristics.

The grammatical articles “a,” “an,” and “the,” as used in this specification, including the claims, are intended to include “at least one” or “one or more” unless otherwise indicated. Thus, the articles are used in this specification to refer to one or more than one (i.e., to “at least one”) of the grammatical objects of the article. By way of example, “a component” means one or more components and, thus, possibly more than one component is contemplated and can be employed or used in an implementation of the described compositions, coatings, and processes. Nevertheless, it is understood that use of the terms “at least one” or “one or more” in some instances, but not others, will not result in any interpretation where failure to use the terms limits objects of the grammatical articles “a,” “an,” and “the” to just one. Further, the use of a singular noun includes the plural, and the use of a plural noun includes the singular, unless the context of the usage requires otherwise.

In this specification, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Any numerical range recited herein includes all sub-ranges subsumed within the recited range. For example, a range of “1 to 10” includes all sub-ranges between (and including) the recited minimum value of 1 and the recited maximum value of 10, that is, having a minimum value equal to or greater than 1 and a maximum value equal to or less than 10. Also, all ranges recited herein are inclusive of the end points of the recited ranges. For example, a range of “1 to 10” includes the end points 1 and 10. Any maximum numerical limitation recited in this specification is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited. All such ranges are inherently described in this specification.

Any patent, publication, or other document identified in this specification is incorporated by reference into this specification in its entirety unless otherwise indicated but only to the extent that the incorporated material does not conflict with existing descriptions, definitions, statements, illustrations, or other disclosure material expressly set forth in this specification. As such, and to the extent necessary, the express disclosure as set forth in this specification supersedes any conflicting material incorporated by reference. Any material, or portion thereof, that is incorporated by reference into this specification, but which conflicts with existing definitions, statements, or other disclosure material set forth herein, is only incorporated to the extent that no conflict arises between that incorporated material and the existing disclosure material. Applicant reserves the right to amend this specification to expressly recite any subject matter, or portion thereof, incorporated by reference. The amendment of this specification to add such incorporated subject matter will comply with the written description, sufficiency of description, and added matter requirements.

Whereas particular examples of this invention have been described above for purposes of illustration, it will be evident to those skilled in the art that numerous variations of the details of the present invention may be made without departing from the invention as defined in the appended claims.

What is claimed is:

1. A method for processing a metallic substrate, the method comprising:
depositing a first layer onto at least a portion of the metallic substrate to create a coated substrate utilizing physical vapor deposition, the first layer is configured to be electroplated; and
electroplating a second layer comprising chromium, a chromium alloy, or a combination thereof onto at least a portion of the first layer to create a plated substrate.

2. The method of claim 1, wherein the physical vapor deposition comprises ion etching.

3. The method of claim 1, wherein the first layer comprises chromium, chromium alloy, iron, an iron alloy, tantalum, a tantalum alloy, tungsten, a tungsten alloy, molybdenum, a molybdenum alloy, niobium, a niobium alloy, or a combination thereof.

4. The method of claim 1, wherein the first layer comprises a thickness in a range of 0.1 microns to 5 microns.

5. The method of claim 1, further comprising depositing an interlayer onto the metallic substrate prior to the first layer, wherein the interlayer comprises tantalum, a tantalum alloy, tungsten, a tungsten alloy, molybdenum, a molybdenum alloy, niobium, a niobium alloy, or a combination thereof. The method of claim 5, wherein the interlayer comprises a thickness in a range of 0.01 microns to 10 microns.

7. The method of claim 5, wherein the metallic substrate comprises a zirconium or zirconium alloy nuclear fuel rod and the depositing the interlayer removes at least a portion of zirconium oxide on a surface of the nuclear fuel rod.

8. The method of claim 1, wherein the metallic substrate comprises a zirconium or zirconium alloy nuclear fuel rod and the depositing the first layer removes at least a portion of zirconium oxide on a surface of the nuclear fuel rod.

9. The method of claim 1, wherein the second layer comprises a thickness in a range of 0.1 microns to 50 microns.

10. The method of claim 1, wherein the first layer comprises a thickness in a range of 3 microns to 5 microns and the second layer comprises a thickness of greater than 15 microns.

11. The method of claim 1, wherein the metallic substrate comprises a nuclear fuel rod and the nuclear fuel rod comprises a zirconium alloy composition comprising, all based on the total weight of the zirconium alloy:
0.5% to 2.0% niobium;
0.7% to 1.5% tin;
0.07% to 0.14% iron;
up to 0.03% carbon;
up to 0.2% oxygen; and
balance zirconium and incidental impurities.

12. The method of claim 1, wherein the plated substrate is suitable for use in a pressurized water reactor.

13. The method of claim 1, wherein the second layer is electroplated at a rate that is at least 10 times faster than a rate the first layer is deposited.

14. A plated nuclear fuel rod comprising:
a substrate comprising zirconium or a zirconium alloy;
a first layer deposited by physical vapor deposition over the substrate, wherein a thickness of the first layer is in a range of 0.1 microns to 5 microns;
a second layer deposited by electroplating, the second layer comprising chromium, a chromium alloy, or a combination thereof, wherein a thickness of the second layer is in a range of 0.1 microns to 50 microns.

15. The plated nuclear fuel rod of claim 14, wherein the first layer comprises chromium, chromium alloy, iron, an iron alloy, tantalum, a tantalum alloy, tungsten, a tungsten alloy, molybdenum, a molybdenum alloy, niobium, a niobium alloy, or a combination thereof.

16. The plated nuclear fuel rod of claim 14, further comprising an interlayer intermediate the substrate and the first layer, wherein the interlayer comprises tantalum, a tantalum alloy, tungsten, a tungsten alloy, molybdenum, a molybdenum alloy, niobium, a niobium alloy, or a combination thereof.

17. The plated nuclear fuel rod of claim 16, wherein the interlayer comprises a thickness in a range of 0.01 microns to 10 microns.

18. The plated nuclear fuel rod of claim 14, wherein the first layer comprises a thickness in a range of 3 microns to 5 microns and the second layer comprises a thickness of greater than 15 microns.

19. The plated nuclear fuel rod of claim 14, wherein the substrate comprises a zirconium alloy composition comprising, all based on the total weight of the zirconium alloy:
0.5% to 2.0% niobium;
0.7% to 1.5% tin;
0.07% to 0.14% iron;
up to 0.3% carbon;
up to 0.2% oxygen; and
balance zirconium and incidental impurities.

20. The plated nuclear fuel rod of claim 14, wherein the nuclear fuel rod is suitable for use in a pressurized water reactor.
